(19) United States
(12) Patent Application Publication
(10) Pub. No.: US 2020/0252036 A1
(43) Pub. Date: Aug. 6, 2020

(54) POWER AMPLIFIER USING MULTI-MODE DISTRIBUTED ACTIVE TRANSFORMER

(71) Applicant: QUALCOMM Incorporated, San Diego, CA (US)

(72) Inventors: Tso-Wei LI, Smyrna, GA (US); Seyed Hossein MIRI LAVASANI, Santa Clara, CA (US); Mazhareddin TAGHIVAND, Santa Clara, CA (US)

(21) Appl. No.: 16/264,460

(22) Filed: Jan. 31, 2019

(51) Int. Cl. H03F 3/26; H01F 7/06; H03F 1/56

(52) U.S. Cl. CPC H03F 3/265; H01F 7/064; H03F 2200/387; H03F 2200/537; H03F 1/56

(57) ABSTRACT

In certain aspects, a multi-mode power amplifier includes first primary inductors, second primary inductors, and switches configured to selectively couple each of the second primary inductors with a respective one of the first primary inductors. The multi-mode power amplifier also includes power amplifiers coupled to the first primary inductors, and a secondary inductor magnetically coupled to the first primary inductors.

### BACKGROUND

### Field

Aspects of the present disclosure relate generally to power amplifiers, and more particularly, to a power amplifier using a multi-mode distributed active transformer.

### Background

Power amplifiers are used in transmitters to amplify radio frequency (RF) signals for transmission. In one power amplifier architecture, a distributed active transformer (DAT) is used to combine the output powers of multiple power amplifiers.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a multi-mode power amplifier. The multi-mode power amplifier includes first primary inductors, second primary inductors, and switches configured to selectively couple each of the second primary inductors with a respective one of the first primary inductors. The multi-mode power amplifier also includes power amplifiers coupled to the first primary inductors, and a secondary inductor magnetically coupled to the first primary inductors.

A second aspect relates to a method for multi-mode operation using a reconfigurable transformer including first primary inductors, second primary inductors, and a secondary inductor. The method includes, in a first mode of operation, driving the first primary inductors to induce a first output voltage on the secondary inductor. The method also includes, in a second mode of operation, coupling each of the second primary inductors with a respective one of the first primary inductors, and driving the first and second primary inductors to induce a second output voltage on the secondary inductor.

A third aspect relates to a multi-mode transformer. The multi-mode transformer includes a first primary side comprising a first plurality of inductors, a second primary side comprising a second plurality of inductors, a plurality of switches configured to selectively couple the second plurality of inductors with respective ones of the first plurality of inductors, and a secondary side.

A fourth aspect relates to an apparatus for multi-mode operation using a reconfigurable transformer including first primary inductors, second primary inductors, and a secondary inductor. The apparatus includes, in a first mode of operation, means for driving the first primary inductors to induce a first output voltage on the secondary inductor. The apparatus also includes, in a second mode of operation, means for coupling each of the second primary inductors with a respective one of the first primary inductors, and means for driving the first and second primary inductors to induce a second output voltage on the secondary inductor.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 shows an example of a power amplifier using a single-mode distributed active transformer.

FIG. 2 shows a schematic of the power amplifier shown in FIG. 1.

FIG. 3 shows a schematic of an exemplary power amplifier using a reconfigurable multi-mode distributed active transformer according to aspects of the present disclosure.

FIG. 4 shows another schematic of an exemplary power amplifier using a reconfigurable multi-mode distributed active transformer according to aspects of the present disclosure.

FIG. 5A shows a lower layer of an exemplary layout for a multi-mode reconfigurable transformer according to certain aspects of the present disclosure.

FIG. 5B shows an upper layer of the exemplary layout for the multi-mode reconfigurable transformer according to certain aspects of the present disclosure.

FIG. 6 is a flowchart illustrating a method for multi-mode operation according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

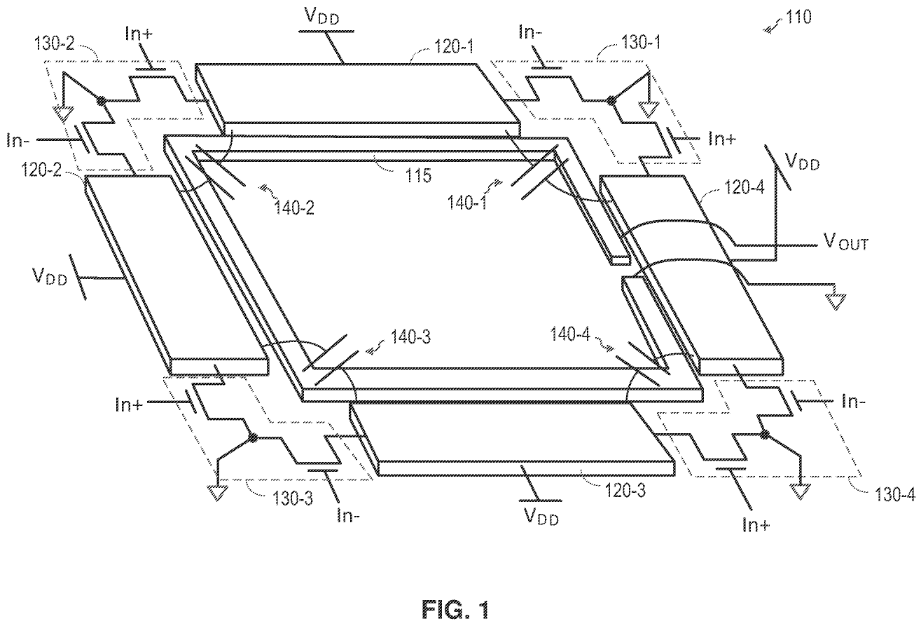

FIG. 1 shows an example of a single-mode distributed active transformer (DAT) power amplifier 110. The DAT power amplifier 110 includes four power amplifiers 130-1 to 130-4 and a transformer configured to combine the output powers of the power amplifiers 130-1 to 130-4. The transformer includes a primary side and a secondary side, the primary side including four primary inductors 120-1 to 120-4 and the secondary side including a secondary inductor 115 magnetically coupled to the primary inductors 120-1 to 120-4. In the example shown in FIG. 1, each of the primary inductors 120-1 to 120-4 is implemented with a slab inductor (also referred to as a slab segment), and the secondary inductor 115 is implemented with a single loop inductor.

Each of the power amplifiers 130-1 to 130-4 is a push-pull amplifier including a pair of n-type metal semiconductor (NMOS) transistors driven by a differential RF signal. In certain aspects, the power amplifiers 130-1 to 130-4 are driven by the same input differential RF signal.

Each of the primary inductors 120-1 to 120-4 is coupled between two neighboring power amplifiers. More particularly, each of the primary inductors 120-1 to 120-4 has a first end (i.e., terminal) coupled to an output of the one of the power amplifiers 130-1 to 130-4 and a second end (i.e., terminal) coupled to an output of opposite phase (i.e., opposite polarity) of another one of the power amplifiers 130-1 to 130-4. In the example shown in FIG. 1, each of the primary inductors 120-1 to 120-4 is coupled between an NMOS transistor of one of the power amplifiers 130-1 to 130-4 and an NMOS transistor of another one of the power amplifiers 130-1 to 130-4, in which the NMOS transistors are driven with opposite phase.

Each of the primary inductors 120-1 to 120-4 has a center tap coupled to the supply voltage V_{DD}, which provides a direct current (DC) bias current for neighboring power amplifiers 130-1 to 130-4. Because each of the primary inductors 120-1 to 120-4 is coupled between amplifier outputs of opposite phase, a virtual alternating current (AC) ground is created at the center tap of each of the primary inductors 120-1 to 120-4.

The DAT power amplifier 110 also includes capacitors 140-1 to 140-4 used for impedance matching, in which each of the capacitors 140-1 to 140-4 is coupled across the differential output of a respective one of the power amplifiers 130-1 to 130-4. In the example shown in FIG. 1, each of the capacitors 140-1 to 140-4 is coupled between the drains of the NMOS transistors of the respective one of the powers amplifiers 130-1 to 130-4.

The capacitors 140-1 to 140-4 and the primary inductors 120-1 to 120-4 form an output matching network that is used to provide impedance matching with the outputs of the power amplifier 130-1 to 130-4. In this regard, the capacitances of the capacitors 140-1 to 140-4 and/or the inductances of the primary inductor 120-1 to 120-4 may be chosen such that the load impedance of the output matching network seen by each of the power amplifiers 130-1 to 130-4 approximately matches the output impedance of the power amplifier 130-1 to 130-4. The impedance matching increases power efficiency.

In operation, the power amplifiers 130-1 to 130-4 are driven by an input differential RF voltage. The power amplifiers 130-1 to 130-4 convert the differential RF voltage into drive currents that drive the primary inductors 120-1 to 120-4, inducing voltages on the secondary inductor 115. The induced voltages are summed at the output of the DAT power amplifier 110 to provide an output voltage V_{OUT} across a load (not shown).

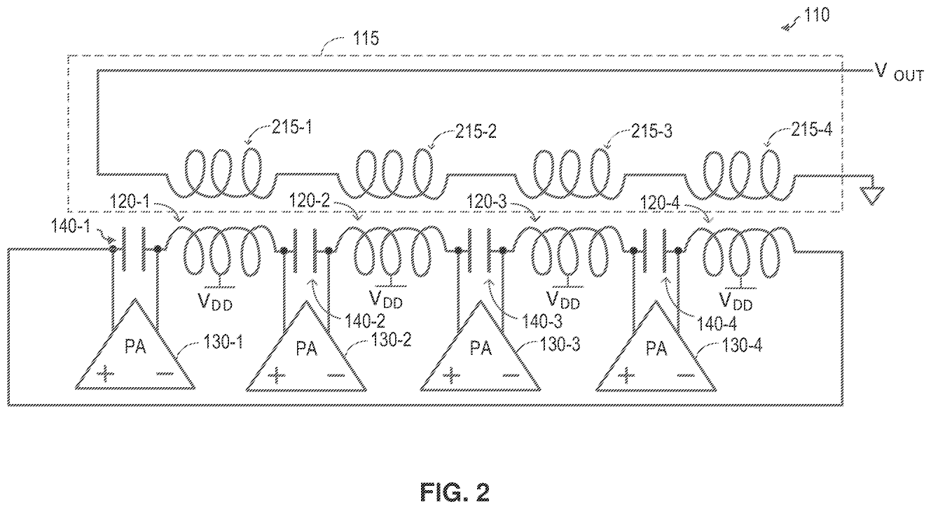

FIG. 2 shows an exemplary schematic of the DAT power amplifier 110. In the example shown in FIG. 2, the secondary inductor 115 is modeled as multiple inductors 215-1 to 215-4 coupled in series.

A limitation of the DAT power amplifier 110 is that the output matching network may only be optimized for one operation mode. For example, for a wireless device with a low-power mode and a high-power mode, the output matching network of the DAT power amplifier 110 may only be optimized for one of these modes. In this example, optimizing the output matching network for the high-power mode sacrifices power efficiency for the low-power mode, and vice versa. This is because the capacitances of the capacitors 140-1 to 140-4 and/or the inductances of the primary inductors 120-1 to 120-4 are tuned in the design phase to optimize the output matching network for a single operation mode. Once the DAT power amplifier 110 is fabricated, the capacitors 140-1 to 140-4 and the primary inductors 120-1 to 120-4 are fixed. Thus, the DAT power amplifier 110 is limited to a single operation mode. In addition, the layout of the DAT power amplifier 110 occupies a relatively large chip area, especially for low-gigahertz (low-GHz) frequency designs.

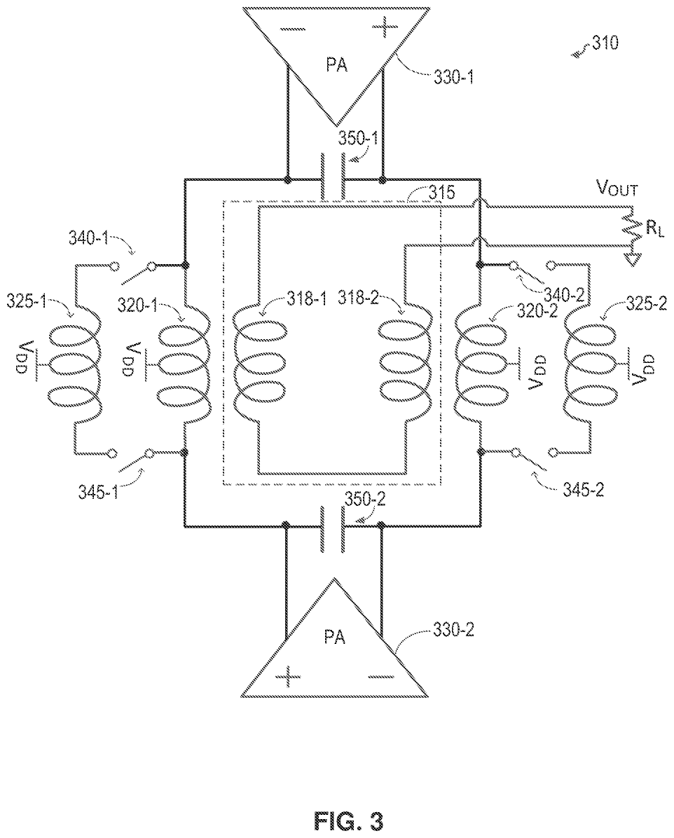

FIG. 3 shows an example of a multi-mode distributed active transformer (DAT) power amplifier 310 according to aspects of the present disclosure. The multi-mode DAT power amplifier 310 includes a reconfigurable transformer that can be reconfigured using switches to provide output impedance matching for different operation modes. This allows the multi-mode DAT power amplifier 310 to operate with high power efficiency in different operation modes. In contrast, the signal-mode DAT power amplifier 110 discussed above is limited to a single operation mode.

The multi-mode DAT power amplifier 310 is discussed below using the example of two operation modes (e.g., power modes). However, it is to be appreciated that the present disclosure is not limited this example, and that the multi-mode DAT power amplifier 310 may be extended to three or more operation modes, as discussed further below.

In the example shown in FIG. 3, the multi-mode DAT power amplifier 310 includes first and second power amplifiers 330-1 and 330-2, and a reconfigurable transformer. The reconfigurable transformer includes a first primary side including first primary inductors 320-1 and 320-2, a second primary side including second primary inductors 325-1 and 325-2, switches 340-1, 340-1, 345-1 and 345-2, and a secondary side including a secondary inductor 315. As discussed further below, the secondary inductor 315 may be implemented with a loop inductor. The secondary inductor 315 is modeled in FIG. 3 as first and second inductors 318-1 and 318-2 coupled in series.

The first and second power amplifiers 330-1 and 330-2 are driven by an input differential RF signal. Each of the power amplifiers 330-1 and 330-2 may be configured to operate in two different power modes (e.g., a low-power mode and a high-power mode). In this example, the output impedance of each of the power amplifiers 330-1 and 330-2 is different for the different power modes. More particularly, the output impedance is lower in the high-power mode to deliver more power. Each of the power amplifiers 330-1 and 330-2 has a differential output comprising two outputs of opposite phase (e.g., opposite polarity). Each of the power amplifiers 330-1 and 330-2 may be implemented with a push/pull amplifier (e.g., a differential NMOS transistor pair). However, it is to be appreciated that the present disclosure is not limited to this example, and that the power amplifiers 330-1 and 330-2 may be implemented with other types of amplifiers. Further, although two power amplifiers 330-1 and 330-2 are shown in the example in FIG. 3, it is to be appreciated that the multi-mode DAT power amplifier 310 may include a different number of power amplifiers.

Each of the first primary inductors 320-1 and 320-2 is coupled between the first and second power amplifiers 330-1 and 330-2. More particularly, each of the first primary inductors 320-1 and 320-2 has a first end (i.e., terminal) coupled to an output of the first power amplifier 330-1 and a second end (i.e., terminal) coupled to an output of opposite phase (i.e., opposite polarity) of the second power amplifier 330-2.

The switches 340-1, 340-2, 345-1 and 345-2 are configured to selectively couple the second primary inductors 325-1 and 325-2 in parallel with respective ones of the first primary inductors 320-1 and 320-2. In certain aspects, the switches 340-1, 340-2, 345-1 and 345-2 couple the second primary inductors 325-1 and 325-2 in parallel with the respective ones of the first primary inductors 320-1 and 320-2 when the switches 340-1, 340-2, 345-1 and 345-2 are closed (i.e., turned on).

In the example shown in FIG. 3, switch 340-1 is coupled between the first end (i.e., terminal) of first primary inductor 320-1 and a first end (i.e., terminal) of second primary inductor 325-1, and switch 345-1 is coupled between the second end (i.e., terminal) of first primary inductor 320-1 and a second end (i.e., terminal) of second primary inductor 325-1. Thus, when the switches 340-1 and 345-1 are closed (i.e., turned on), second primary inductor 325-1 is coupled in parallel with first primary inductor 320-1. When switches 340-1 and 345-1 are open (i.e., turned off), second primary inductor 325-1 is decoupled from first primary inductor 320-1

Switch 340-2 is coupled between the first end (i.e., terminal) of first primary inductor 320-2 and a first end (i.e., terminal) of second primary inductor 325-2, and switch 345-2 is coupled between the second end (i.e., terminal) of first primary inductor 320-2 and a second end (i.e., terminal) of second primary inductor 325-2. Thus, when the switches 340-2 and 345-2 are closed (i.e., turned on), second primary inductor 325-2 is coupled in parallel with first primary inductor 320-2. When switches 340-2 and 345-2 are open (i.e., turned off), second primary inductor 325-2 is decoupled from first primary inductor 320-2.

Each of the first primary inductors 320-1 and 320-2 has a center tap coupled to the supply voltage V_{DD}, and each of the second primary inductors 325-1 and 325-2 has center tap coupled to the supply voltage V_{DD}, as shown in FIG. 3.

The DAT power amplifier 110 also includes capacitors 350-1 and 350-2 used for impedance matching. Capacitor 350-1 is coupled across the differential output of the first power amplifier 330-1, and capacitor 350-2 is coupled across the differential output of the second power amplifier 330-2. As discussed above, the differential output of each power amplifier 330-1 and 330-2 comprises outputs of opposite phase (i.e., opposite polarity). Thus, capacitor 350-1 is coupled between the outputs of the first power amplifier 330-1, and capacitor 350-2 is coupled between the outputs of the second power amplifier 330-2.

In operation, the reconfigurable transformer is configured to operate the multi-mode DAT power amplifier 310 in the high-power mode or the low-power mode by controlling the on/off states of the switches 340-1, 340-2, 345-1 and 345-2. In certain aspect, the switches 340-1, 340-2, 345-1 and 345-2 are configured to selectively couple the second primary inductors 325-1 and 325-2 in parallel with the respective ones of the first primary inductors 320-1 and 320-2 based on the power mode of the power amplifiers 330-1 and 330-2. In these aspects, the switches 340-1, 340-2, 345-1 and 345-2 couple the second primary inductors 325-1 and 325-2 in parallel with the respective ones of the first primary inductors 320-1 and 320-2 in the high-power mode, and decouple the second primary inductors 325-1 and 325-2 from the respective ones of the first primary inductors 320-1 and 320-2 in the low-power mode.

To operate the multi-mode DAT power amplifier 310 in the low-power mode, the switches 340-1, 340-2, 345-1 and 345-2 are open (i.e., turned off). In this case, the second primary inductors 325-1 and 325-2 are decoupled from the first primary inductors 320-1 and 320-2. The first primary inductors 320-1 and 320-2 and the capacitors 350-1 and 350-2 form an output matching network that is used to provide impedance matching with the outputs of the power amplifiers 330-1 and 330-2 in the low-power mode. The second primary inductors 325-1 and 325-2 are not part of the output matching network in the low-power mode since the second primary inductors 325-1 and 325-2 are decoupled from the first primary inductors 320-1 and 320-2 in the low-power mode.

In certain aspects, the inductances of the first primary inductors 320-1 and 320-2 are chosen (e.g., in the design phase) such that the load impedance of the output matching network seen by each of the power amplifiers 330-1 and 330-2 approximately matches the output impedance of the power amplifier 330-1 and 330-2 in the low-power mode. The impedance matching provides high power efficiency in the low-power mode.

In the low-power mode, the power amplifiers 330-1 and 330-2 convert the input differential RF voltage into drive currents that drive the first primary inductors 320-1 and 320-2, inducing voltages on the secondary inductor 315. The induced voltages on the secondary inductor 315 are summed at the output of the DAT power amplifier 310 to provide an output voltage V_{OUT} across a load (represented as load resistor R_{L}). The second primary inductors 325-1 and 325-2 are not driven by the power amplifiers 330-1 and 330-2 in the low-power mode.

To operate the multi-mode DAT power amplifier 310 in the high-power mode, the switches 340-1, 340-2, 345-1 and 345-2 are closed (i.e., turned on). In this case, each of the second primary inductors 325-1 and 325-2 is coupled in parallel with the respective one of the first primary inductors 320-1 and 320-2. The parallel combinations of the first and second primary inductors 320-1, 320-2, 325-1 and 325-2 and the capacitors 350-1 and 350-2 form an output matching network that is used to provide impedance matching with the outputs of the power amplifier 330-1 and 330-2 in the high-power mode.

In certain aspects, the inductances of the second primary inductors 325-1 are 325-2 are chosen (e.g., in the design phase) such that the load impedance of the output matching network seen by each of the power amplifiers 330-1 and 330-2 approximately matches the output impedance of the power amplifier 330-1 and 330-2 in the high-power mode. The impedance matching provides high power efficiency in the high-power mode.

Note that the inductances of the first primary inductors 320-1 and 320-2 are chosen to provide output impedance matching for the low-power mode. The inductances of the second primary inductors 325-1 and 325-2 are chosen such that the inductances of the parallel combinations of the first and second primary inductors 320-1, 320-2, 325-1 and 325-2 provide output impedance matching for the high-power mode. Coupling the second primary inductors 325-1 and 325-2 in parallel with the first primary inductors 320-1 and 320-2 reduces the inductances in the output matching network.

In the high-power mode, the power amplifiers 330-1 and 330-2 convert the input differential RF voltage into drive currents that drive the parallel combinations of the first and second primary inductors 320-1, 320-2, 325-1 and 325-2, inducing voltages on the secondary inductor 315. The induced voltages on the secondary inductor 315 are summed at the output of the DAT power amplifier 310 to provide an output voltage V_{OUT} across the load (represented as load resistor R_{L}).

Thus, the multi-mode DAT power amplifier 310 can be reconfigured to support multi-mode operation. In the example discussed above, the reconfigurable transformer can be reconfigured using switches 340-1, 340-5, 345-1 and 345-2 to provide output impedance matching for the low-power mode and the high-power mode. This allows the multi-mode DAT power amplifier 310 to operate with high power efficiency (e.g., at least 40%) in the low-power mode and the high-power mode. In contrast, the signal-mode DAT power amplifier 110 is optimized for a single operation mode.

Although the multi-mode DAT power amplifier 310 is discussed above using the example of two operation modes (i.e., the low-power mode and the high-power mode), it is to be appreciated that the present disclosure is not limited this example. The multi-mode DAT power amplifier 310 may be extended to three or more operation modes, for example, by adding additional inductors and switches to the reconfigurable transformer. The additional inductors and switches allow the reconfigurable transformer to be reconfigured to provide output impedance matching for one or more additional operation modes. Further, although the multi-mode DAT power amplifier 310 has two channels in the example shown in FIG. 3, it is to be appreciated that the present disclosure is not limited to this example. The multi-mode DAT power amplifier 310 may be expanded to four channels, for example, by adding additional power amplifiers, inductors and switches.

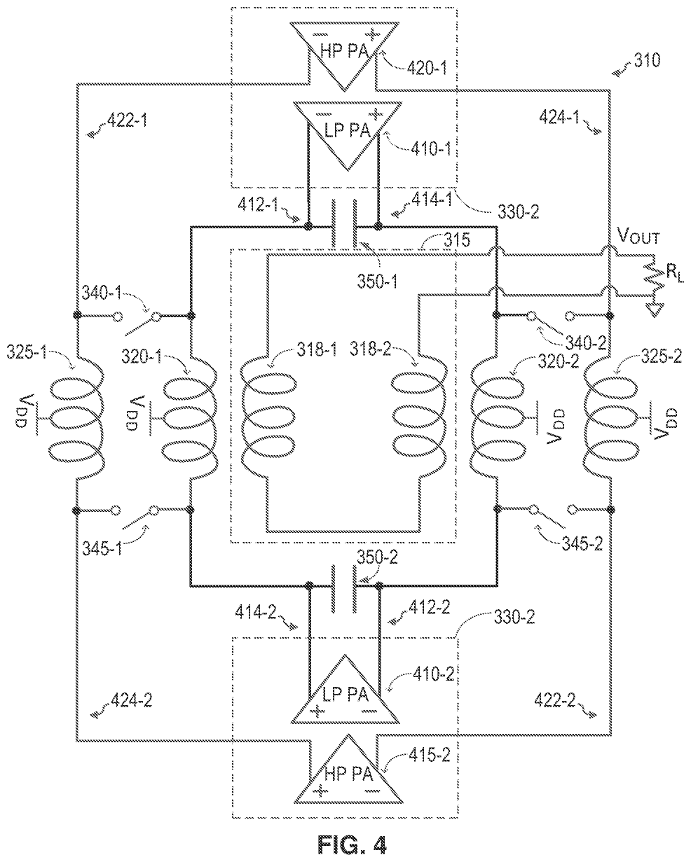

As discussed above, each of the power amplifiers 330-1 and 330-2 may be configured to operate in the low-power mode or the high-power mode. In this regard, the first power amplifier 330-1 may include a first low-power (LP) power amplifier 410-1 and a first high-power (HP) power amplifier 420-1, an example of which is shown in FIG. 4. Similarly, the second power amplifier 330-2 may include a second LP power amplifier 410-2 and a second HP power amplifier 420-2. In this example, the HP power amplifiers 420-1 and 420-2 may have lower output impedances than the LP power amplifiers 410-1 and 410-2 for higher power delivery. In the low-power mode, the LP power amplifiers 410-1 and 410-2 are driven by an input differential RF signal, and, in the high-power mode, the HP power amplifiers 420-1 and 420-2 are driven by an input differential RF signal.

The LP power amplifiers 410-1 and 410-2 (i.e., power amplifiers associated with the low-power mode) are coupled to the first primary side of the transformer, which includes the first primary inductors 320-1 to 320-2. In the example shown in FIG. 4, the first LP power amplifier 410-1 has first and second outputs 412-1 and 414-1 of opposite phase (i.e., opposite polarity). The first output 412-1 is coupled to the first end (i.e., terminal) of first primary inductor 320-1, and the second output 414-1 is coupled to the first end (i.e., terminal) of first primary inductor 320-2. In this example, capacitor 350-1 is coupled between the first and second outputs 412-1 and 414-1 of the first LP power amplifier 410-1 to provide impedance matching.

The second LP power amplifier 410-2 has first and second outputs 412-2 and 414-2 of opposite phase (i.e., opposite polarity). The first output 412-2 is coupled to the second end (i.e., terminal) of first primary inductor 320-2, and the second output 414-2 is coupled to the second end (i.e., terminal) of first primary inductor 320-1. In this example, capacitor 350-2 is coupled between the first and second outputs 412-2 and 414-2 of the second LP power amplifier 410-2 to provide impedance matching.

The HP power amplifiers 420-1 and 420-2 (i.e., power amplifiers associated with the high-power mode) are coupled to the second primary side of the transformer, which includes the second primary inductors 325-1 to 325-2. The switches 340-1, 340-2, 345-1 and 345-2 selectively couple the HP power amplifiers 420-1 and 420-2 with the first primary side of the transformer based on the power mode, as discussed further below. The first HP power amplifier 420-1 has first and second outputs 422-1 and 424-1 of opposite phase (i.e., opposite polarity). The first output 422-1 is coupled to the first end (i.e., terminal) of second primary inductor 325-1, and the second output 424-1 is coupled to the first end (i.e., terminal) of second primary inductor 325-2. When switches 340-1 and 340-2 are closed in the high-power mode, capacitor 350-1 is coupled between the first and second outputs 422-1 and 424-1 of the first HP power amplifier 420-1 to provide impedance matching in the high-power mode.

The second HP power amplifier 420-2 has first and second outputs 422-2 and 424-2 of opposite phase (i.e., opposite polarity). The first output 422-2 is coupled to the second end (i.e., terminal) of second primary inductor 325-2, and the second output 424-2 is coupled to the second end (i.e., terminal) of second primary inductor 325-1. When switches 345-1 and 345-2 are closed in the high-power mode, capacitor 350-2 is coupled between the first and second outputs 422-2 and 424-2 of the second HP power amplifier 420-2 to provide impedance matching in the high-power mode.

In the low-power mode, the switches 340-1, 340-2, 345-1 and 345-2 are open (i.e., turned off), which decouples the second primary inductors 325-1 and 325-2 from the first primary inductors 320-1 and 320-2. In the low-power mode, the primary inductors 320-1 and 320-2 are used in conjunction with the capacitors 350-1 and 350-2 to provide output matching network with the outputs of the LP power amplifiers 410-1 and 410-2. In this regard, the inductances of the first primary inductors 320-1 and 320-2 are chosen (e.g., in the design phase) such that the load impedance of the output matching network seen by each of the LP power amplifiers 410-1 and 410-2 approximately matches the output impedance of the LP power amplifier 410-1 and 410-2.

In the low-power mode, the LP power amplifiers 410-1 and 410-2 are driven by an input different RF voltage. The LP power amplifiers 410-1 and 410-2 convert the input differential RF voltage into drive currents that drive the first primary inductors 320-1 and 320-2, inducing voltages on the secondary inductor 315. The induced voltages on the secondary inductor 315 are summed at the output of the DAT power amplifier 310 to provide an output voltage V_{OUT} across a load (represented as load resistor R_{L}). Thus, in the low-power mode, the LP power amplifiers 410-1 and 410-2 drive the first primary side of the transformer.

In the high-power mode, the switches 340-1, 340-2, 345-1 and 345-2 are closed (i.e., turned on), which couples the second primary inductors 325-1 and 325-2 in parallel with the first primary inductors 320-1 and 320-2. This also couples the HP power amplifiers 420-1 and 420-2 with the first primary side of the transformer via the switches 340-1, 340-2, 345-1 and 345-2. In the high-power mode, the parallel combinations of the first and second primary inductors 320-1, 320-2, 325-1 and 325-2 are used in conjunction with the capacitors 350-1 and 350-2 to provide output matching network with the outputs of the HP power amplifiers 420-1 and 420-2. In this regard, the inductances of the second primary inductors 325-1 and 325-2 are chosen (e.g., in the design phase) such that the load impedance of the output matching network seen by each of the HP power amplifiers 420-1 and 420-2 approximately matches the output impedance of the HP power amplifier 420-1 and 420-2.

In the high-power mode, the HP power amplifiers 420-1 and 420-2 are driven by an input different RF voltage. The HP power amplifiers 420-1 and 420-2 convert the input differential RF voltage into drive currents that drive the parallel combinations of the first and second primary inductors 320-1, 320-2, 325-1 and 325-2, inducing voltages on the secondary inductor 315. The induced voltages on the secondary inductor 315 are summed at the output of the DAT power amplifier 310 to provide an output voltage V_{OUT} across a load (represented as load resistor R_{L}). Thus, in the high-power mode, the HP power amplifiers 420-1 and 420-2 drive the second primary side and the first primary side of the transformer, which are coupled in the high-power mode via the switches 340-1, 340-2, 345-1 and 345-2.

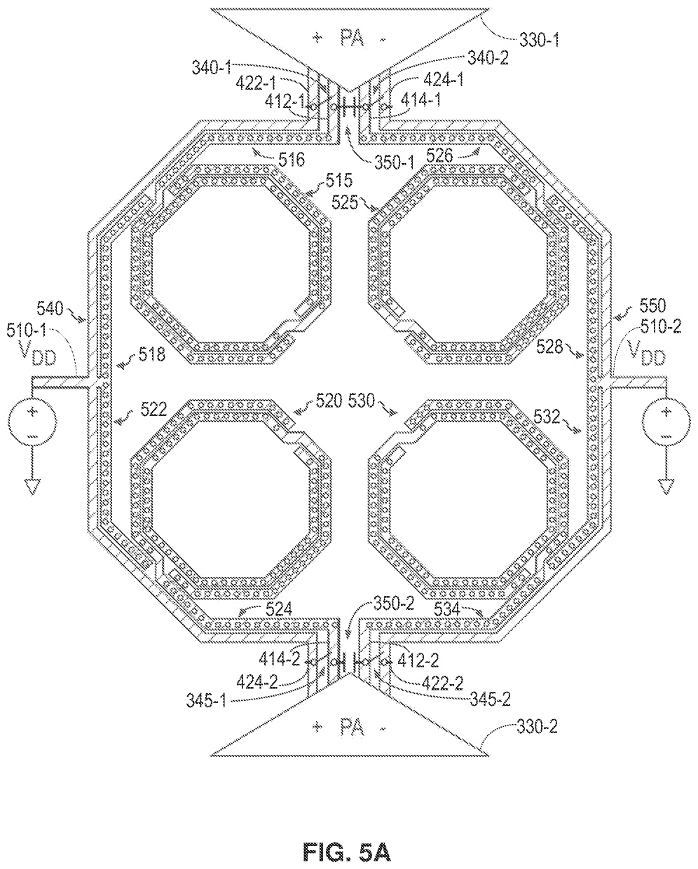

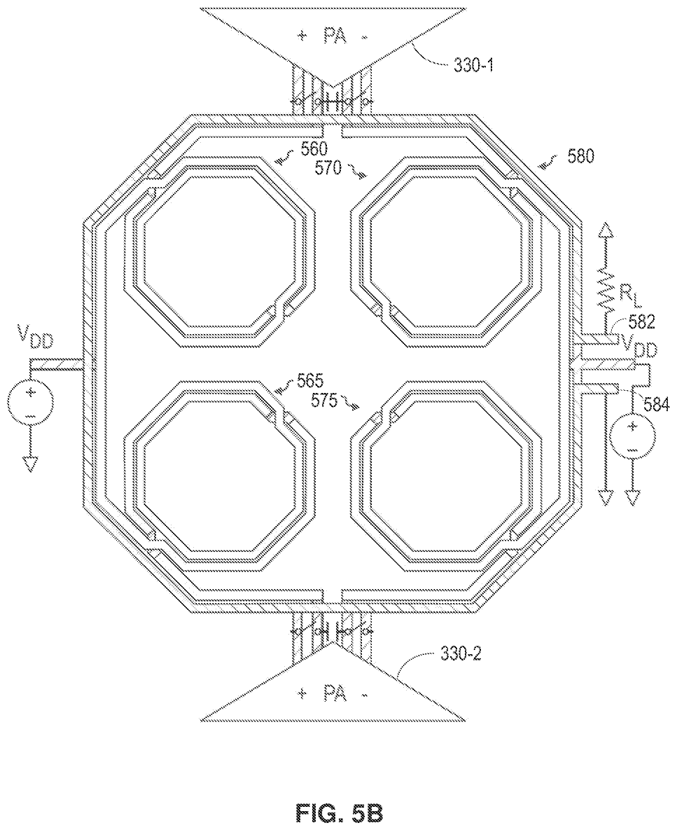

FIGS. 5A and 5B show an exemplary layout for the reconfigurable transformer of the multi-mode DAT power amplifier 310 according to certain aspects of the present disclosure. In this example, the reconfigurable transformer is a multi-layer structure. In this regard, FIG. 5A shows a top view of a lower layer of the transformer and FIG. 5B shows a top view of an upper layer of the transformer.

In the example shown in FIG. 5A, the lower layer includes first and second lower coils 515 and 520, which may be formed from a lower metal layer (e.g., using photolithographic and etching techniques known in the art). In this example, each of the first and second lower coils 515 and 520 has two turns. The first lower coil 515 is coupled to the first output 412-1 of the first LP power amplifier 410-1 (shown in FIG. 4) by metal trace 516, and coupled to a first center tap 510-1 by metal trace 518. The second lower coil 520 is coupled to the first center tap 510-1 by metal trace 522, and coupled to the second output 414-2 of the second LP power amplifier 410-2 by metal trace 524. As discussed further below, the first and second lower coils 515 and 520 form part of first primary inductor 320-1.

Referring to FIG. 5B, the upper layer includes first and second upper coils 560 and 565, which may be formed from an upper metal layer (i.e., a metal layer above the lower metal layer). In this example, each of the first and second upper coils 560 and 565 has two turns. The first upper coil 560 overlaps the first lower coil 515 and is coupled to the first lower coil 515 by multiple vias (shown as small circles in FIG. 5A) distributed along the paths of the coils 515 and 560. In this disclosure, “via” refers to a vertical interconnect structure that interconnects two metal layers. Similarly, the second upper coil 565 overlaps the second lower coil 520 and is coupled to the second lower coil 520 by multiple vias distributed along the paths of the coils 520 and 565.

The first and second lower coils 515 and 520 and the first and second upper coils 560 and 565 form first primary inductor 320-1. The first center tap 510-1 coupled between the first and second lower coils 515 and 520 provides the center tap for first primary inductor 320-1, and is coupled to the supply voltage V_{DD}. In this example, the structure of first primary inductor 320-1 is symmetric about the first center tap 510-1.

In the example shown in FIG. 5A, the lower layer also includes third and fourth lower coils 525 and 530, which may be formed from the lower metal layer. In this example, each of the third and fourth lower coils 525 and 530 has two turns. The third lower coil 525 is coupled to the second output 414-1 of the first LP power amplifier 410-1 (shown in FIG. 4) by metal trace 526, and coupled to a second center tap 520-2 by metal trace 528. The fourth lower coil 530 is coupled to the second center tap 520-2 by metal trace 532, and coupled to the first output 412-2 of the second LP power amplifier 410-2 by metal trace 534. As discussed further below, the third and fourth lower coils 525 and 530 form part of first primary inductor 320-2.

Referring to FIG. 5B, the upper layer includes third and fourth upper coils 570 and 575, which may be formed from the upper metal layer. In this example, each of the third and fourth upper coils 570 and 575 has two turns. The third upper coil 570 overlaps the third lower coil 525 and is coupled to the third lower coil 525 by multiple vias distributed along the paths of the coils 525 and 570. Similarly, the fourth upper coil 575 overlaps the fourth lower coil 530 and is coupled to the fourth lower coil 530 by multiple vias distributed along the paths of the coils 530 and 575.

The third and fourth lower coils 525 and 530 and the third and fourth upper coils 570 and 575 form first primary inductor 320-2. The second center tap 510-2 coupled between the third and fourth lower coils 525 and 530 provides the center tap for first primary inductor 320-2, and is coupled to the supply voltage V_{DD}. In this example, the structure of first primary inductor 320-2 is symmetric about the second center tap 510-2.

In the example shown in FIG. 5A, the lower layer also includes a first outer metal trace 540 coupled between the first output 422-1 of the first HP power amplifier 420-1 (shown in FIG. 4) and the second output 424-2 of the second HP power amplifier 420-2. A center (i.e., midpoint) of the first outer metal trace 540 is coupled to the first center tap 510-1. In this example, the first outer metal trace 540 forms second primary inductor 325-1. The first center tap 510-1 provides the center tap for second primary inductor 325-1, and the structure of second primary inductor 325-1 is symmetric about the first center tap 510-1. When switches 340-1 and 345-1 are closed, second primary inductor 325-1 is coupled in parallel with first primary inductor 320-1.

The lower layer further includes a second outer metal trace 560 coupled between the second output 414-1 of the first HP power amplifier 420-1 (shown in FIG. 4) and the first output 422-2 of the second HP power amplifier 420-2. A center (i.e., midpoint) of the second outer metal trace 560 is coupled to the second center tap 510-2. In this example, the second outer metal trace 560 forms second primary inductor 325-2. The second center tap 510-2 provides the center tap for second primary inductor 325-2, and the structure of second primary inductor 325-2 is symmetric about the second center tap 510-2. When switches 340-2 and 345-2 are closed, second primary inductor 325-2 is coupled in parallel with first primary inductor 320-2.

Referring to FIG. 5B, the upper layer also includes a metal loop 580 forming the secondary inductor 315. The metal loop 580 may be formed from the upper metal layer (e.g., using photolithographic and etching techniques known in the art). In this example, the outer metal traces 540 and 550 forming the second primary inductors 325-1 and 325-2 are located underneath the metal loop 580 forming the secondary inductor 315. Also, the coils 515, 520, 525, 530, 560, 565, 570 and 575 forming the first primary inductors 320-1 and 320-2 are located inside the metal loop 580 forming the secondary inductor 315. This layout reduces area compared with the layout in FIG. 1, in which the primary inductors 120-1 to 120-4 are placed around the secondary inductor 115 (e.g., outside the loop of the secondary inductor 115).

In the example in FIG. 5B, the metal loop 580 forming the secondary inductor 315 has a first end 582 (i.e., terminal) and a second end 584 (i.e., terminal) providing the output of the multi-mode DAT power amplifier 310. In this example, the first end 582 is coupled to the load (represented as load resistor R_{L}) and the second end 584 is coupled to ground.

Note that FIG. 5B shows the upper layer structure of the reconfigurable transformer above the lower layer structure of the reconfigurable transformer. For ease of illustration, the lower layer structure is not labeled with reference numbers in FIG. 5B. Also, note that small gaps in the conduction path of the first lower coil 515 are bridged by the first upper coil 560 since these coils are coupled by vias, and vice versa. The same applies to the other coils.

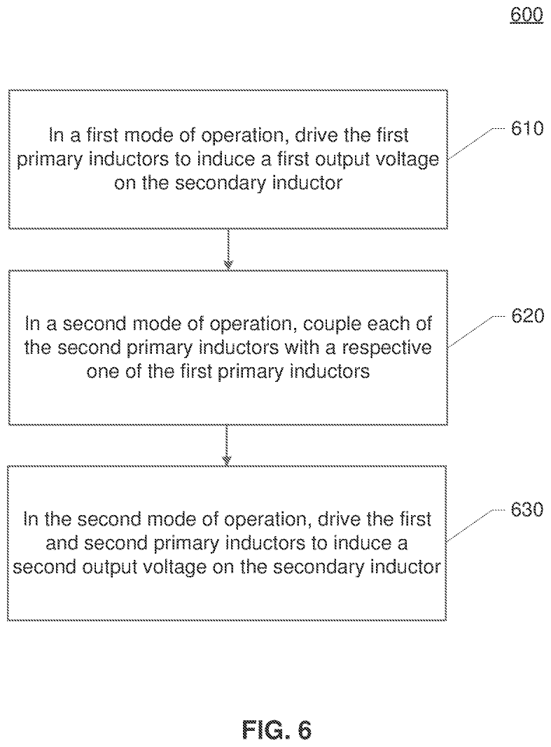

FIG. 6 is a flowchart illustrating a method for multi-mode operation using a reconfigurable transformer including first primary inductors (e.g., first primary inductors 320-1 and 320-2), second primary inductors (e.g., second primary inductors 325-1 and 325-2), and a secondary inductor (e.g., secondary inductor 315).

At block 610, in a first mode of operation, the first primary inductors are driven to induce a first output voltage on the secondary inductor. For example, the first mode of operation may correspond to the low-power mode discussed above. The first primary inductors may be driven using multiple power amplifiers (e.g., power amplifiers 330-1 and 330-2).

At block 620, in a second mode of operation, each of the second primary inductors is coupled with a respective one of the first primary inductors. For example, the second mode of operation may correspond to the high-power mode discussed above. Also, each of the second primary inductors may be coupled in parallel with a respective one of the first primary inductors. At block 630, in the second mode of operation, the first and second primary inductors are driven to induce a second output voltage on the secondary inductor. For the example in which each of the second primary inductors is coupled in parallel with the respective one of the first primary inductors, the multiple power amplifiers (e.g., power amplifiers 330-1 and 330-2) may drive parallel combinations of the first and second primary inductors.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A multi-mode power amplifier, comprising:
first primary inductors;
second primary inductors;
switches configured to selectively couple each of the second primary inductors with a respective one of the first primary inductors;
power amplifiers coupled to the first primary inductors; and
a secondary inductor magnetically coupled to the first primary inductors.

2. The multi-mode power amplifier of claim 1, wherein the switches are configured to couple each of the second primary inductors in parallel with the respective one of the first primary inductors when the switches are closed.

3. The multi-mode power amplifier of claim 2, wherein the power amplifiers are configured to drive parallel combinations of the first primary inductors and the second primary inductors when the switches are closed.

4. The multi-mode power amplifier of claim 2, wherein the switches are configured to decouple each of the second primary inductors from the respective one of the first primary inductors when the switches are open.

5. The multi-mode power amplifier of claim 1, wherein each of the switches is coupled between a respective end of one of the first primary inductors and a respective end of one of the second primary inductors.

6. The multi-mode power amplifier of claim 1, further comprising capacitors, wherein each of the capacitors is coupled across a differential output of a respective one of the power amplifiers.

7. The multi-mode power amplifier of claim 1, wherein each of the first primary inductors is coupled between a respective output of one of the power amplifiers and a respective output of opposite polarity of another one of the power amplifiers.

8. The multi-mode power amplifier of claim 1, wherein the secondary inductor comprises a metal loop.

9. The multi-mode power amplifier of claim 8, wherein the first primary inductors are located inside the metal loop.

10. The multi-mode power amplifier of claim 9, wherein each of the first primary inductors comprises two coils with a center tap coupled between the two coils and coupled to a supply voltage.

11. The multi-mode power amplifier of claim 8, wherein each of the second primary inductors comprises a metal trace underneath the metal loop.

12. A method for multi-mode operation using a reconfigurable transformer including first primary inductors, second primary inductors, and a secondary inductor, comprising:
in a first mode of operation, driving the first primary inductors to induce a first output voltage on the secondary inductor;
in a second mode of operation,
coupling each of the second primary inductors with a respective one of the first primary inductors; and
driving the first and second primary inductors to induce a second output voltage on the secondary inductor.

13. The method of claim 12, wherein coupling each of the second primary inductors with the respective one of the first primary inductors comprises coupling each of the second primary inductors in parallel with the respective one of the first primary inductors.

14. The method of claim 12, wherein each of the secondary primary inductors is decoupled from the respective one of the first primary inductors in the first mode of operation.

15. The method of claim 12, wherein the first primary inductors are driven in the first mode of operation using power amplifiers, the first and second primary inductors are driven in the second mode of operation using the power amplifiers, and an output power of each of the power amplifiers is higher in the second mode of operation than the first mode of operation.

16. The method of claim 12, wherein coupling each of the second primary inductors with the respective one of the first primary inductors comprises closing switches between the second primary inductors and the first primary inductors.

17. A multi-mode transformer, comprising:
a first primary side comprising a first plurality of inductors;
a second primary side comprising a second plurality of inductors;
a plurality of switches configured to selectively couple the second plurality of inductors with respective ones of the first plurality of inductors; and
a secondary side.

18. The multi-mode transformer of claim 17, wherein the first plurality of inductors are coupled to a plurality of power amplifiers, and wherein the plurality of switches are configured to selectively couple the second plurality of inductors with the respective ones of the first plurality of inductors based on a power mode of the plurality of power amplifiers.

19. The multi-mode transformer of claim 18, wherein the plurality of power amplifiers includes a power amplifier associated with a low-power mode and a power amplifier associated with a high-power mode.

20. The multi-mode transformer of claim 19, wherein the power amplifier associated with the low-power mode is coupled to the first primary side and the power amplifier associated with the high-power mode is coupled to the second primary side.

21. The multi-mode transformer of claim 19, wherein the plurality of switches are configured to selectively couple the power amplifier associated with the high-power mode to the first primary side.

22. The multi-mode transformer of claim 17, wherein the plurality of switches are configured to selectively couple the second plurality of inductors in parallel with the respective ones of the first plurality of inductors.

23. An apparatus for multi-mode operation using a reconfigurable transformer including first primary inductors, second primary inductors, and a secondary inductor, the apparatus comprising:
in a first mode of operation, means for driving the first primary inductors to induce a first output voltage on the secondary inductor;
in a second mode of operation,
means for coupling each of the second primary inductors with a respective one of the first primary inductors; and
means for driving the first and second primary inductors to induce a second output voltage on the secondary inductor.

24. The apparatus of claim 23, wherein the means for coupling each of the second primary inductors with the respective one of the first primary inductors comprises means for coupling each of the second primary inductors in parallel with the respective one of the first primary inductors.

25. The apparatus of claim 23, wherein each of the secondary primary inductors is decoupled from the respective one of the first primary inductors in the first mode of operation.

26. The apparatus of claim 23, wherein the means for driving the first and second primary inductors in the second mode of operation has a higher output power than the means for driving the first primary inductors in the first mode of operation.
